(19) United States
(12) Patent Application Publication
(10) Pub. No.: US 2025/0344351 A1
(43) Pub. Date: Nov. 6, 2025

(54) SYSTEMS AND METHODS FOR EFFICIENTLY COOLING EXPANSION CARDS IN RISER ASSEMBLIES

(71) Applicant: Dell Products L.P., Round Rock, TX (US)

(72) Inventors: Rachel MAZZINI, Dallas, TX (US); Evangelos KOUTSAVDIS, Leander, TX (US)

(73) Assignee: Dell Products L.P., Round Rock, TX (US)

(21) Appl. No.: 18/653,730

(22) Filed: May 2, 2024

(51) Int. Cl. H05K 7/20; G06F 1/20; H05K 7/14

(52) U.S. Cl. CPC H05K 7/20727; G06F 1/20; H05K 7/1487

(57) ABSTRACT

An information handling system may include a chassis and an information handling resource assembly, which may be configured to carry one or more information handling resources. The information handling resource assembly may include a main structure and a slidable wall mechanically coupled to the main structure, and the slidable wall may be configured to translate between a closed position and an open position.

### TECHNICAL FIELD

The present disclosure relates in general to information handling systems, and more particularly to systems and methods for efficiently cooling expansion cards in riser assemblies.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Many information handling systems utilize one or more riser cards. A riser card is a printed circuit board that gives a motherboard of the information handling system the option for additional expansion cards to be added to the information handling system. Thus, a riser card is usually coupled to a motherboard receptacle connector via an edge connector, and may include one or more receptacle connectors mounted on the riser card to receive expansion cards in order to electrically couple such expansion cards to the motherboard. Accordingly, in general, the main purpose of a riser card may be to change the orientation of the expansion cards such that they fit a limited space within casing.

In order to provide mechanical structure for the riser card, its connectors, and expansion cards coupled to the riser card, a riser mechanical assembly may be used to house the riser card, its connectors, and expansion cards coupled to the riser card, and may also include mechanical features to mechanically retain the edge connector of the riser card within the receptacle connector of the motherboard. Often, such riser mechanical assemblies may have a minimal or open concept design for riser modularization. However, such open concept designs may result in inefficient cooling of the expansion cards. Accordingly, systems and methods that enable efficient routing of airflow in riser mechanical assemblies may be desired.

### SUMMARY

In accordance with the teachings of the present disclosure, the disadvantages and problems associated with existing approaches to efficiently cooling expansion cards in riser mechanical assemblies may be reduced or eliminated.

In accordance with embodiments of the present disclosure, an information handling system may include a chassis and an information handling resource assembly, which may be configured to carry one or more information handling resources. The information handling resource assembly may include a main structure and a slidable wall mechanically coupled to the main structure, and the slidable wall may be configured to translate between a closed position and an open position.

In accordance with embodiments of the present disclosure, an inlet structure may be configured to mechanically couple to an information handling resource assembly, which may be configured to carry one or more information handling resources. The inlet structure may be further configured to direct airflow within the information 20 handling resource assembly.

In accordance with embodiments of the present disclosure, a method of making an information handling resource assembly may include forming a main structure and mechanically coupling the main structure to a slidable wall. The slidable wall may be configured to translate between a closed position and an open position such that the information handling resource assembly may be configured to carry one or more information handling resources.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIGS. 2A-2C illustrate perspective views of selected components of an example enclosable riser assembly mechanically coupled to an example inlet structure, in accordance with embodiments of the present disclosure; and

FIGS. 3A-3C illustrate various perspective views of a mechanism of assembly of the enclosable riser assembly and the inlet structure of FIGS. 2A-2C, in accordance with embodiments of the present disclosure.

### DETAILED DESCRIPTION

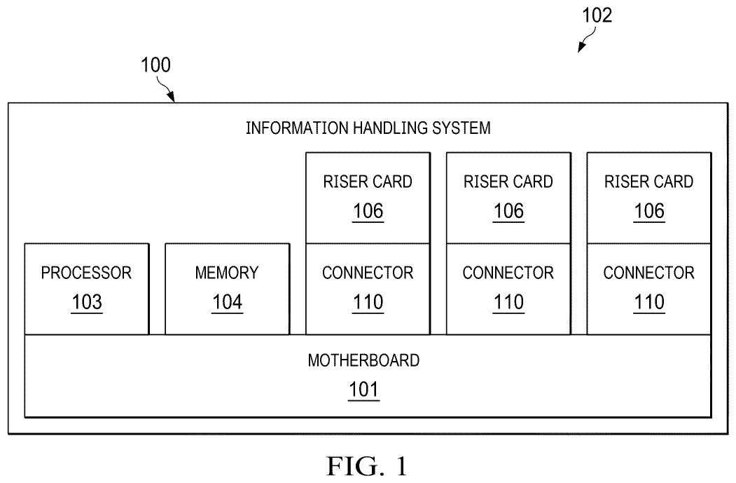

Preferred embodiments and their advantages are best understood by reference to FIGS. 1 through 3C, wherein like numbers are used to indicate like and corresponding parts.

For the purposes of this disclosure, an information handling system may include any instrumentality or aggregate of instrumentalities operable to compute, classify, process, retrieve, transmit, receive, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”), microcontroller, or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems (BIOSs), buses, memories, I/O devices and/or interfaces, storage resources, network interfaces, motherboards, and/or any other components and/or elements of an information handling system.

For the purposes of this disclosure, circuit boards may broadly refer to printed circuit boards (PCBs), printed wiring boards (PWBs), printed wiring assemblies (PWAs), etched wiring boards, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIG. 1 illustrates a block diagram of selected components of an example information handling system 102. In some embodiments, information handling system 102 may comprise a server. In other embodiments, information handling system 102 may comprise networking equipment for facilitating communication over a communication network. In yet other embodiments, information handling system 102 may comprise a personal computer, such as a laptop, notebook, or desktop computer.

As shown in FIG. 1, information handling system 102 may include a chassis 100 that houses a motherboard 101, a processor 103 coupled to motherboard 101, a memory 104 coupled to motherboard 101, connectors 110 mechanically and electrically coupled to motherboard 101, and a plurality of riser cards 106 electrically coupled to motherboard 101 via respective connectors 110.

Chassis 100 may include any suitable housing or enclosure configured to house the various components of information handling system 102, and may be constructed from metal, plastic, and/or any other suitable material.

Motherboard 101 may comprise a circuit board configured to provide structural support for one or more information handling resources of information handling system 102 and/or electrically couple one or more of such information handling resources to each other and/or to other electric or electronic components external to information handling system 102.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in a storage resource, memory system 104, and/or another component of information handling system 102.

Memory 104 may be communicatively coupled to processor 103 and may comprise any system, device, or apparatus operable to retain program instructions or data for a period of time (e.g., computer-readable media). Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off. In particular embodiments, memory 104 may comprise dynamic random access memory (DRAM).

A connector 110 may comprise any system, device, or apparatus fixedly mounted on motherboard 101 and may be constructed to mechanically couple a corresponding riser card 106 to motherboard 101 and to electrically couple such riser card 106 to motherboard 101, processor 103, and/or other components of information handling system 102. A connector 110 may comprise a socket including a receptacle slot or other opening configured to removably receive a corresponding mating edge connector of riser card 106.

A riser card 106 may comprise a circuit board enabling the option for additional expansion cards to be coupled to motherboard 101. A riser card 106 may be coupled to a connector 110 via an edge connector (not explicitly shown in FIG. 1), and may include one or more receptacle connectors mounted (not explicitly shown in FIG. 1) on a riser card 106 to receive expansion cards in order to electrically couple such expansion cards to motherboard 101.

In addition to motherboard 101, processor 103, memory 104, riser cards 106, and connectors 110, information handling system 102 may include one or more other information handling resources.

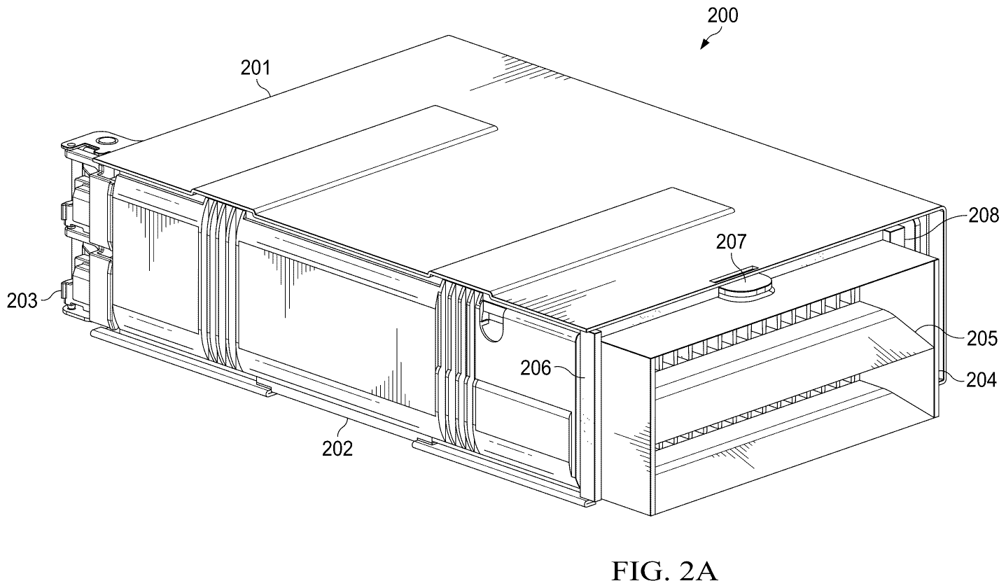

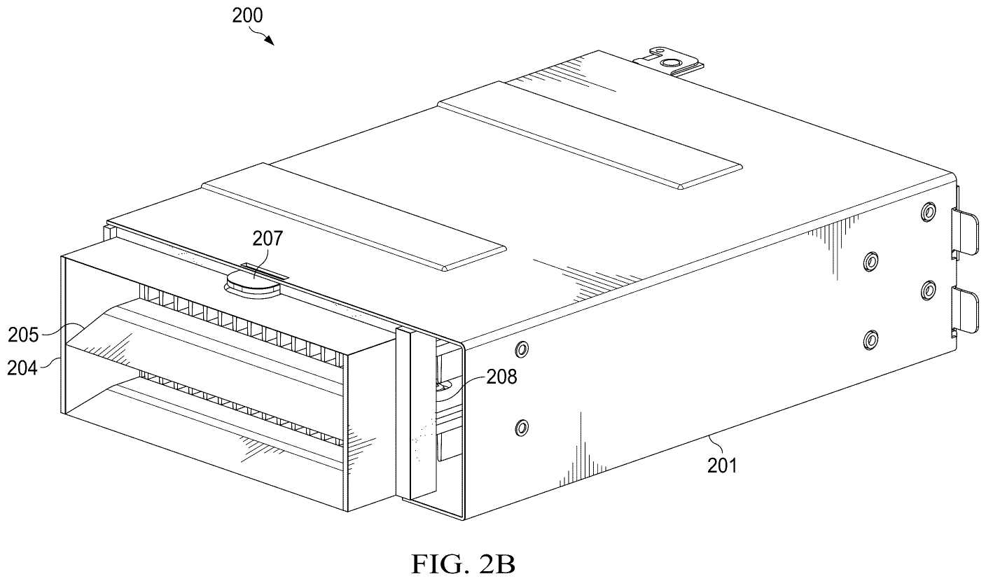

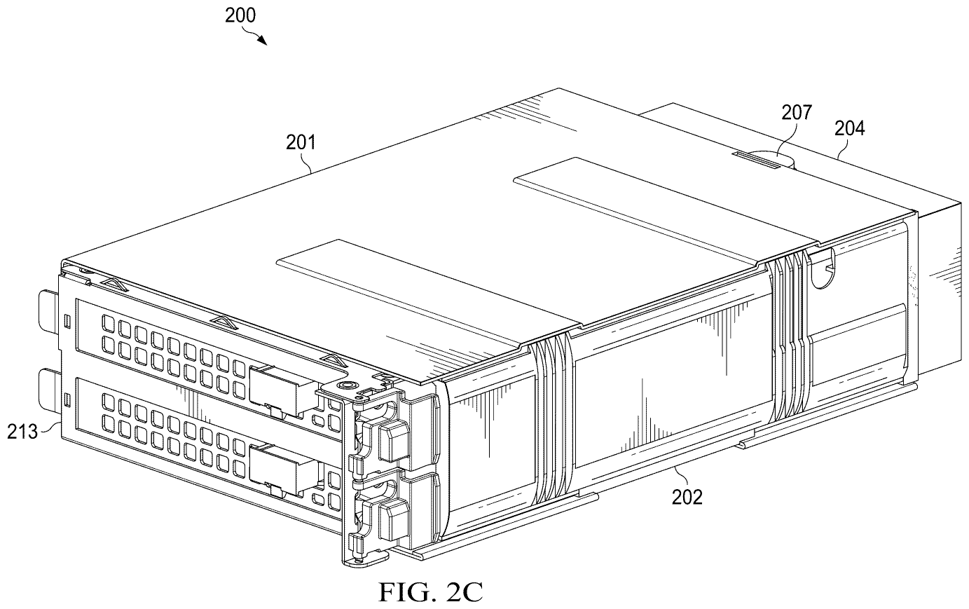

FIGS. 2A-2B illustrate front perspective views of selected components of an example enclosable riser assembly 200 mechanically coupled to an example inlet structure 204, in accordance with embodiments of the present disclosure. In some embodiments, a chassis of an information handling system may house one or more enclosable riser assemblies 200, as well as other information handling resources. Enclosable riser assembly 200 may be configured to house one or more riser cards, connectors of such one or more riser cards, and any expansion cards coupled to each riser card.

In some embodiments, enclosable riser assembly 200 may comprise a bracket 201 and a slidable wall 202 and may further be configured to mechanically couple to and decouple from inlet structure 204. Bracket 201 may be substantially C-shaped and may be mechanically coupled to slidable wall 202. As described in more detail below, slidable wall 202 may be configured to slidably extend from bracket 201 to an “open” position such that expansion cards may be inserted in to enclosable riser assembly 200 and electrically coupled to a riser card housed therein. In some embodiments, foam 206 may be coupled to slidable wall 202 such that foam 206 is interfaced between slidable wall 202, bracket 201, and inlet structure 204 when slidable wall 202 is in a “closed” position, thus directing airflow and minimizing air leakage along edges where slidable wall 202, bracket 201, and inlet structure 204 interface. Enclosable riser assembly 200 may further comprise latch 203, which may be configured to secure bracket 201.

As further shown in FIGS. 2A-2B, enclosable riser assembly 200 may be configured to mechanically couple to and decouple from inlet structure 204. Inlet structure 204 may be configured to effectively direct airflow within enclosable riser assembly 200 (e.g., towards expansion card heatsinks). As shown in FIGS. 2A-2B, inlet structure 204 may comprise a rectangular hollow bisected by aerodynamic member 205. Inlet structure 204 may further comprise a tab 207 configured to facilitate mechanical coupling and decoupling of inlet structure 204 with enclosable riser assembly 200. Thus, inlet structure 204 may be modular and may be swapped out with a different inlet structure. In some embodiments, foam 208 may be coupled to inlet structure 204 such that foam 208 is interfaced between inlet structure 204, bracket 201, and slidable wall 202 when inlet structure 204 is mechanically coupled to bracket 201, thus directing airflow and minimizing air leakage along edges where inlet structure 204, bracket 201, and slidable wall 202 interface. As described above, inlet structure 204 may efficiently direct airflow within enclosable riser assembly 200 (e.g., towards expansion card heatsinks). Airflow may exit enclosable riser assembly 200 at openings in a rear wall 213 of enclosed riser assembly 200 (see FIG. 2C).

While FIGS. 2A-2B show inlet structure 204 comprising a rectangular hollow bisected by aerodynamic member 205, one of ordinary skill in the art may appreciate that inlet structure 204 may comprise any suitable configuration to direct airflow within enclosable riser assembly 200. In some embodiments, configuration of inlet structure 204 may depend on cooling requirements of particular expansion cards housed in enclosable riser assembly 200. As described above, inlet structure 204 may be configured to mechanically couple to and decouple from enclosable riser assembly 200, thus allowing inlet structure 204 to be swapped or exchanged for another inlet structure having a different configuration.

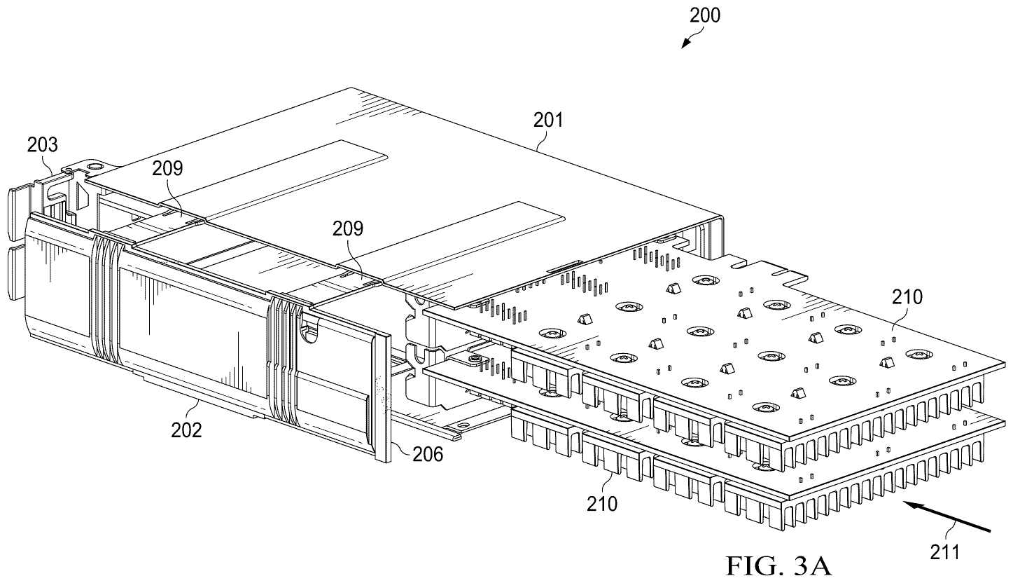

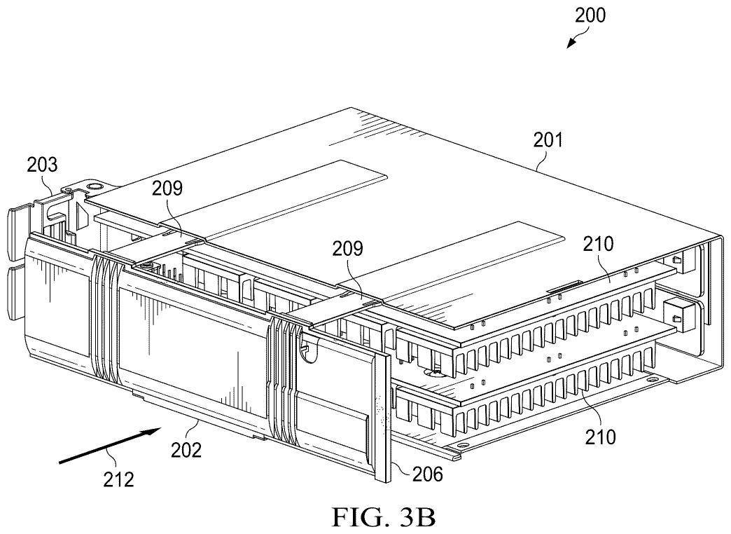

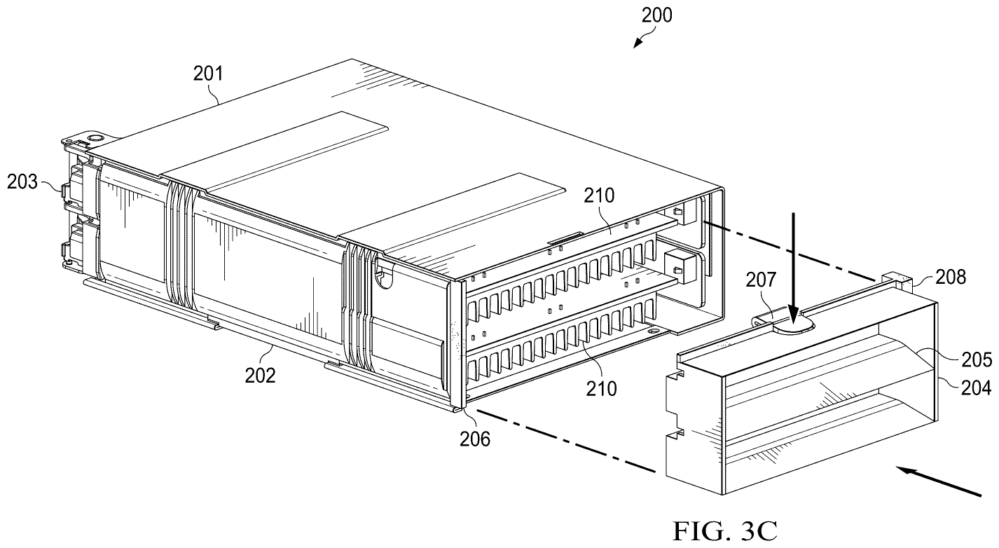

FIGS. 3A-3C illustrate various perspective views of a mechanism of assembly of enclosable riser assembly 200 and inlet structure 204 of FIGS. 2A-2C, in accordance with embodiments of the present disclosure.

As shown in FIG. 3A, slidable wall 202 may be mechanically coupled to bracket 201 via a pair of rails 209 extending substantially perpendicular from slidable wall 202. In some embodiments, slidable wall 202 may be configured to move between a “closed” position (e.g., a position in which edges of bracket 201 and edges of slidable wall 202 are substantially close such that air leakage between edges of bracket 201 and edges of slidable wall 202 where bracket 201 and slidable wall 202 interface may be minimized, as shown in FIGS. 2A-2C and 3C) and an “open” position (e.g., a position in which rails 209 are extended from bracket 201 such that there is substantial space between edges of bracket 201 and edges of slidable wall 202, as shown in FIGS. 3A-3B).

While FIGS. 3A-3B show a pair of rails 209, one of ordinary skill in the art would understand that enclosable riser assembly 200 may comprise any suitable number of rails 209, arranged in any suitable configuration, such that rails 209 may mechanically couple bracket 201 to slidable wall 202 such that slidable wall 202 may slidably translate between the closed position and an open position.

As further shown in FIG. 3A, when slidable wall 202 is in an open position, a user may insert one or more expansion cards 210 into enclosable riser assembly 200 in the direction of arrow 211. A user may then electrically couple one or more expansion cards 210 to a riser card housed in enclosed riser assembly 200 (not shown), and move slidable wall 202 in the direction of arrow 212 (as shown in FIG. 3B) to the closed position (as shown in FIG. 3C). A user may then secure bracket 201 with latch 203 (as shown in FIG. 3C).

A user may then mechanically couple inlet structure 204 to a front side of enclosable riser assembly 200. As shown in FIG. 3C, in some embodiments, a user may apply a downward force to tab 207 such that a portion of tab 207 may be inserted beneath a top surface of bracket 201 and secure inlet structure 204 to enclosable riser assembly 200 (as shown in FIGS. 2A-2C). Assembled enclosable riser assembly 200, including inlet structure 204 mechanically coupled thereto, may then be mechanically coupled to a chassis.

While the terms “front,” “rear,” and “top” are used for purposes of clarity and exposition, such terms are not intended to limit enclosable riser assembly 200 to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. An information handling system comprising:
a chassis; and
an information handling resource assembly configured to carry one or more information handling resources, wherein the information handling resource assembly comprises:
a main structure; and
a slidable wall mechanically coupled to the main structure, wherein the slidable wall is configured to translate between a closed position and an open position.

2. The information handling system of claim 1, wherein the information handling resource assembly is further configured to mechanically couple to an inlet structure configured to guide airflow within the information handling resource assembly.

3. The information handling system of claim 1, further comprising an inlet structure configured to mechanically couple to the information handling resource assembly and guide airflow within the information handling resource assembly.

4. The information handling system of claim 3, wherein:
the information handling resource assembly further comprises foam coupled to the slidable wall and foam coupled to the inlet structure; and
wherein the foam coupled to the slidable wall and the foam coupled to the inlet structure are configured to prevent air from leaking at edges where the slidable wall, inlet structure, and main structure interface.

5. The information handling system of claim 3, wherein the inlet structure comprises:
a substantially rectangular hollow bisected by an aerodynamic member; and
a tab configured to mechanically couple the inlet structure to the information handling resource assembly.

6. The information handling system of claim 3, wherein the inlet structure is further configured to direct airflow towards one or more heatsinks associated with the one or more information handling resources.

7. The information handling system of claim 1, wherein the main structure comprises a substantially C-shaped bracket.

8. The information handling system of claim 1, wherein the information handling resource assembly is configured to receive the one or more information handling resources when the slidable wall is in the open position.

9. The information handling system of claim 1, wherein the slidable wall is mechanically coupled to the main structure via one or more rails, wherein the one or more rails are configured to extend from the main structure when the slidable wall is in the open position.

10. An inlet structure configured to mechanically couple to an information handling resource assembly configured to carry one or more information handling resources, wherein the inlet structure is configured to direct airflow within the information handling resource assembly.

11. The inlet structure of claim 10, wherein the inlet structure comprises:
a substantially rectangular hollow bisected by an aerodynamic member; and
a tab configured to mechanically couple the inlet structure to the information handling resource assembly.

12. The inlet structure of claim 10, wherein the inlet structure is further configured to direct airflow towards one or more heatsinks associated with the one or more information handling resources.

13. A method of making an information handling resource assembly comprising:
forming a main structure; and
mechanically coupling the main structure to a slidable wall configured to translate between a closed position and an open position;
such that:
the information handling resource assembly is configured to carry one or more information handling resources.

14. The method of claim 13, wherein the information handling resource assembly is further configured to mechanically couple to an inlet structure, wherein the inlet structure is configured to guide airflow within the information handling resource assembly.

15. The method of claim 13, further comprising mechanically coupling an inlet structure to the information handling resource assembly, wherein the inlet structure is configured to guide airflow within the information handling resource assembly.

16. The method of claim 15, wherein the inlet structure comprises:
a substantially rectangular hollow bisected by an aerodynamic member; and
a tab configured to mechanically couple the inlet structure to the information handling resource assembly.

17. The method of claim 15, wherein the inlet structure is configured to direct airflow towards one or more heatsinks associated with the one or more information handling resources.

18. The method of claim 15, further comprising:
mechanically coupling foam to the slidable wall; and
mechanically coupling foam to the inlet structure;
wherein the foam coupled to the slidable wall and the foam coupled to the inlet structure are configured to prevent air from leaking at edges where the slidable wall, inlet structure, and main structure interface.

19. The method of claim 13, wherein the main structure comprises a substantially C-shaped bracket.

20. The method of claim 13, wherein the information handling resource assembly is configured to receive the one or more information handling resources when the slidable wall is in the open position.

21. The method of claim 13, wherein mechanically coupling the main structure to the slidable wall comprises mechanically coupling the main structure to one or more rails mechanically coupled to and extending substantially perpendicular from the slidable wall, wherein the one or more rails are configured to extend from the main structure when the slidable wall is in the open position.
